(19) United States
(12) Patent Application Publication
(10) Pub. No.: US 2026/0360851 A1
(43) Pub. Date: Nov. 12, 2026

(54) BATTERY THERMAL MANAGEMENT AND SAFETY METHOD AND DEVICE FOR IMPLEMENTING SAME

(71) Applicant: TOTALENERGIES ONETECH, Courbevoie (FR)

(72) Inventors: Nicolas CHAMPAGNE, Solaize (FR); Jonathan RAISIN, Solaize (FR)

(73) Assignee: TOTALENERGIES ONETECH, Courbevoie (FR)

(21) Appl. No.: 18/997,434

(22) PCT Filed: Jul. 24, 2023
(86) PCT No.: PCT/EP2023/070392

§ 371 Date: Jan. 21, 2025

(30) Foreign Application Priority Data
Jul. 25, 2022 (FR) FR2207612

(51) Int. Cl. H01M 10/63; G01R 31/385; H01M 10/613; H01M 10/625; H01M 10/6568; H01M 10/6569; H01M 10/663

(52) U.S. Cl. CPC H01M 10/63; G01R 31/385; H01M 10/613; H01M 10/6568; H01M 10/6569; H01M 10/663; H01M 10/625

(57) ABSTRACT

The present invention relates to a thermal management and safety method for a battery in a device, the device comprising a battery and a cooling circuit, the battery comprising a plurality of modules, each module comprising a plurality of cells and the cooling circuit comprising a loop for circulating a coolant and control valves for controlling the flow of the coolant upstream of each module, the method comprising the following steps: a) a step of detecting a fault in at least one cell of a module, b) when a fault is detected, a step of modulating the flow, which step comprises increasing the flow of the coolant in the module or the modules comprising at least one faulty cell.

### TECHNICAL FIELD

The present invention relates to thermal management and safety of batteries comprising several cells, in particular for mobile or stationary applications.

### PRIOR ART

A battery is a system for producing electricity wherein chemical energy is converted into electrical energy. The chemical energy consists of electrochemically active compounds deposited on at least one face of electrodes arranged in the electrochemical generator. The electrical energy is produced by electrochemical reactions during a discharge of the electrochemical cell.

A battery comprises a plurality of electrochemical cells. A lithium-ion electrochemical cell is based on the principle of reversible insertion of lithium into a host structure, in an electrochemically active way.

In the field of electrochemical cells such as Li-Ion cells, the temperature of the cells has to be managed in order to maintain the temperature within an adequate range of the cell.

Lithium-ion batteries are generally used at temperatures ranging from 0 to 40 °C. In case of runaway, some cells can reach temperatures on the order of 400 to 800 °C.

Batteries are commonly used in mobile or stationary applications.

Stationary applications include batteries for storing energy, e.g. solar storage batteries, and also energy storage systems.

Mobile applications include automotive applications, such as electric vehicles, or aviation.

The battery is likely to generate a large amount of heat, in particular during a quick charging. Thus, it is necessary to be able to extract the heat. For cooling batteries, air and water combined, if appropriate, with anti-freeze, are known. However, with the appearance of increasingly complex battery and heat generating systems, the cooling methods are not always sufficient.

Moreover, one of the proven risks in battery pack systems comprising a plurality of cells is the propagation of a fault that may appear on one or a plurality of electrochemical cells which are constituents of the battery, said battery generally comprising between 100 and 10,000 cells. Such faults can have various causes (short circuit, high temperature (e.g. >150 °C), loss of integrity of the cell during an accident, etc.) and result in a very sharp increase in the temperature of the cell (which can go up to 800 °C or even higher) associated with an ejection of hot gases. Safety systems are obviously put in place to prevent such potential faults. In such a framework, it is appropriate to consider the case of the occurrence of a fault. The safety system will then aim to prevent the propagation of the thermal runaway. Indeed, the strong heat generated by the faulty cell can become the source of thermal runaway of neighboring cells.

Document EP 2 873 541 discloses a cooling system for hybrid or electric vehicle batteries comprising a circulation of a heat transfer coolant in a main loop and branches controlled according to the temperature of the heat transfer fluid. The present document describes a relatively complex system involving branch circuits. The present document does not address the same problems as the present invention.

Document WO 2021/062305 discloses a technology of thermal management of the passenger compartment of a vehicle. Said document is not aimed at a thermal management and safety system for batteries and said document proposes to circulate a coolant when the system exceeds a certain threshold.

Document EP 4 027 435 discloses to prevent a flame from propagating in a battery by circulating a coolant when the system exceeds a certain threshold.

It is thus a subject matter of the present invention to propose a new of thermal management and of battery safety system that is simple to implement, aimed at preventing the propagation of the thermal runaway of a faulty cell.

### SUMMARY OF THE INVENTION

More precisely, the present invention relates to a method of thermal management and of safety of a battery in a device, said device comprising a battery and a cooling circuit, the battery including a plurality of modules, each module including a plurality of cells and the cooling circuit comprising a circulation loop for a coolant and regulating valves for regulating the flow-rate of said coolant upstream of each module, the method comprising the steps:
a) A step of detecting a fault in at least one cell of a module,
b) When a fault is detected, a flow-rate modulation step that includes an increase in the coolant flow-rate through the module(s) containing at least one faulty cell.

According to one embodiment, at least 50% of the flow-rate of the coolant is redirected to the module or modules including at least one faulty cell, preferably at least 70% of the flow-rate, else preferably at least 90% of the flow-rate, or even 100% of the flow-rate of the coolant is directed to the module or modules including at least one faulty cell.

According to one embodiment, step a) comprises the following successive steps:
a1 Setting a threshold value for at least one parameter selected from temperature, voltage and current,
a2 Measuring at least one parameter selected from temperature, voltage and current during battery operation,
a3 Detecting a fault when the measured parameter is above or below the threshold value set during step a1.

According to one embodiment, the parameter is the temperature of the coolant, said method comprising:
a1 Setting a temperature threshold value not to be exceeded,
a2 Measuring the coolant temperature at the outlet of each module or at the outlet of each cell,
a3 Detecting a fault in at least one given module or cell, when the temperature measured at the outlet of that module or cell exceeds the temperature threshold value,
b) Redirecting at least part of the flow-rate of the coolant toward said faulty module or the module including said faulty cell.

According to one embodiment, the parameter is the temperature of each module or of each cell, said method comprising:
a1 Setting of a temperature threshold value, not to be exceeded, of each module or of each cell,
a2 Measuring the temperature of each module of each cell,
a3 Detecting a fault in at least one given module or cell, when the measured temperature of said module or said cell exceeds the temperature threshold value,
b) Redirecting at least part of the flow-rate of the coolant toward said faulty module or the module including said faulty cell.

According to one embodiment, step a) comprises the following successive steps:
a1 Setting a threshold value for the change of at least one parameter during a given time, said at least one parameter being selected from temperature, voltage and current,
a2 Measuring said parameter during battery operation,
a3 Detecting a fault in at least one given module or at least one given cell, when said threshold value is exceeded,

According to one embodiment, step b) further comprises a reduction in the flow-rate of the coolant in the module or modules which do not have faulty cells.

According to one embodiment, the modulation step b) is implemented until the faulty cell or cells return to nominal operation.

A further subject matter of the invention is a device for implementing said method according to the invention, said device comprising:
A battery including a plurality of modules, each module including a plurality of electrochemical cells,
A cooling system including:
   a circulation loop for a coolant,
   at least one valve upstream of each module for controlling the flow-rate of coolant.

According to one embodiment, said at least one valve is a shut-off valve serving to stop the circulation of the flow-rate in the module not comprising any faulty cell(s).

According to one embodiment, the device further comprises a control unit for detecting at least one faulty cell.

According to one embodiment, the device further comprises at least one sensor at the outlet of each module or each cell, making it possible to measure at least one parameter chosen from the temperature of the coolant and the current.

According to one embodiment, the device further comprises an air conditioning circuit wherein a refrigerant fluid flows.

Preferably, the device comprises the cooling circuit further comprising at least one heat exchanger intended to exchange heat with the air or with a refrigerant fluid of the air conditioning circuit.

According to one embodiment, the device comprises a cooling circuit further comprising at least one heat exchanger intended to exchange heat with the air.

The management method of the invention makes it possible to prevent the risks of thermal runaway and to very quickly reduce the propagation of a thermal runaway.

The management method of the invention is easy to implement. Same can be implemented in mobile or stationary applications.

The management method of the invention does not require any external supply of coolant, but on the contrary uses the coolant already present in the circuit for cooling the battery to prevent the propagation of a thermal runaway.

Thereby, the method of the invention can be used in batteries for storing energy, e.g. solar storage batteries, and also energy storage systems.

Thereby, the method of the invention can be used in electric or hybrid vehicles or in aviation.

Unless otherwise indicated, the quantities in a product are expressed by weight, with respect to the total weight of the product.

### BRIEF DESCRIPTION OF FIGURES

FIG. 1 represents the trend in the oil pump flow-rate in the reference case.

FIG. 2 represents the flow-rate of the coolant in the module during runaway and in the parallel modules.

FIG. 3 represents the trend of the coolant temperature at different positions of the battery in the reference case.

FIG. 4 represents the trend of the temperature of the cells in the module during runway in the reference case.

FIG. 5 shows the trend of the flow-rate distribution between the runaway module and the parallel modules for different levels of flow-rate modulation in the modules.

FIG. 6 shows the trend in the oil pump flow-rate in the module during runaway for different levels of flow-rate modulation in the modules.

FIG. 7 shows the trend in the oil temperature at the input of the battery pack for different levels of flow-rate modulation in the modules.

FIG. 8 shows the trend of the oil temperature at the outlet of the module during runaway for different levels of flow-rate modulation in the modules.

FIG. 9 shows the trend of the oil temperature at the outlet of the battery pack for different levels of flow-rate modulation in the modules.

FIG. 10 shows the trend in the temperature of the adjacent cells to the cell undergoing runaway, for different levels of flow-rate modulation in the modules.

FIG. 11 shows the trend of temperature of the cell during runaway for different levels of flow-rate modulation in the modules.

### DETAILED DESCRIPTION

The present invention relates to a method for thermal management and safety of a battery in a device, said device comprising a battery and a cooling circuit.

According to the present invention, the battery includes a plurality of modules, each module including a plurality of electrochemical cells.

Preferably, the modules of the battery are located in parallel with each other.

The thermal and safety management method according to the invention is typically implemented using a cooling circuit comprising a circulation loop for a coolant, said coolant being in direct contact with the cells.

Thereby, according to one embodiment, the coolant is in direct contact with the cells. Indeed, the non-aqueous nature of the coolant makes it possible to operate the direct contact so that the cooling and the heat transfer are more efficient. On the other hand, an aqueous coolant could not be brought into direct contact, and would thus have less efficiency with regard to the cooling and to the heat transfer.

By direct contact, it is understood according to the invention that the coolant and the cells touch without there being any obstacles therebetween. Thereof optimizes the exchange surface between the coolant and the cells and achieves a better heat transfer efficiency so as to prevent or retard the phenomenon of thermal runaway.

In nominal operation, the coolant circulates with a given flow-rate, preferably with an identical flow-rate in each of the modules of the battery.

The coolant used according to the invention is preferably a non-aqueous coolant. The coolant used according to the invention advantageously has insulating properties, e.g. a resistivity at 30 °C, measured as per the standard ASTM D1169, greater than or equal to 1 Mohm·m, preferably greater than or equal to 100 Mohm·m. Thereby, typically, the coolant used according to the invention has a conductivity of less than or equal to 10⁻⁶ ohm⁻¹·m⁻¹ preferably less than or equal to 10⁻⁸ ohm⁻¹·m⁻¹. Such properties are particularly advantageous when the coolant is used via direct contact with the cells.

The coolant used according to the invention comprises one or a plurality of base oils, preferably in a total content from 70% to 100% by weight, preferably ranging from 70 to 99% by weight, else preferably from 80 to 98% by weight, preferentially from 85 to 95% by weight, with respect to the total weight of the cooling composition.

According to one embodiment, the coolant comprises 100% by weight of base oil(s), with respect to the total weight of the coolant.

Such base oils can be chosen from base oils conventionally used in the field of lubricating oils, such as mineral oils, either synthetic or natural, animal or plant oils or mixtures thereof.

There can be a mixture of a plurality of base oils, e.g. a mixture of two, three, or four base oils.

The base oils used in the coolants used according to the invention can be, more particularly, mineral or synthetic oils belonging to groups I to V as per the classes defined by the API classification (or the equivalents thereof as per the ATIEL classification) and shown in Table 1 hereinafter, or mixtures thereof.

TABLE 1

| | Concentration | | Viscosity |
|---|---|---|---|
| | of saturated | Sulfur | index |
| | [oils] | concentration | (VI) |
| Group I | <90% | >0.03% | 80 ≤ VI < 120 |
| Mineral oils | | | |
| Group II | ≥90% | ≤0.03% | 80 ≤ VI < 120 |
| Hydrocracked oils | | | |
| Group III | ≥90% | ≤0.03% | ≥120 |
| Hydro-isomerized or | | | |
| hydrocracked oils | | | |

| | |
|---|---|
| Group IV | Polyalphaolefines (PAO) |
| Group V | Esters and other bases not included in groups I to IV |

The mineral base oils include any type of base oil obtained by atmospheric distillation and vacuum distillation of crude oil, followed by refining operations such as solvent extraction, deasphalting, solvent dewaxing, hydrotreatment, hydrocracking, hydroisomerization and hydrofinishing.

Mixtures of synthetic and mineral oils which can be biosourced or recycled, can further be used.

The base oils of the coolants according to the invention can further be chosen from synthetic oils, such as certain carboxylic acid esters and alcohol esters, polyalphaolefins (PAO), and polyalkylene anti-freeze (PAG) obtained by polymerization or copolymerization of alkylene oxides comprising from 2 to 8 carbon atoms, in particular from 2 to 4 carbon atoms.

The PAOs used as base oils are e.g. obtained from monomers comprising from 4 to 32 carbon atoms, e.g. from octene or decene. The weight-average molecular weight of the PAO can vary quite significantly. Preferentially, the weight-average molecular weight of the PAO is less than 600 Da. The weight-average molecular weight of the PAO can further range from 100 to 600 Da, from 150 to 600 Da, or further from 200 to 600 Da.

Additional additives can be used in the coolant used in the invention. The additives include antioxidants, anti-corrosion additives, anti-foam additives and pour point depressants.

According to a particularly preferred embodiment, the cooling composition used according to the invention comprises at least one antioxidant additive. The antioxidant additive generally makes it possible to delay the degradation of the composition in service. Such degradation most often shows as a deposit formation, in the presence of sludge or in an increase in the viscosity of the composition.

Antioxidant additives in particular act as radical inhibitors or destroyers of hydroperoxides. The antioxidant additives commonly used include phenolic antioxidants, amine antioxidant additives, phosphosulfur antioxidant additives.

The coolant used according to the invention can comprise 0.1 to 2% by weight of at least one antioxidant additive, with respect to the total weight of the coolant. The coolant used according to the invention can comprise at least one anti-corrosion additive. The anti-corrosion additive advantageously delays or prevents the corrosion of the metal parts of the battery.

The coolant used according to the invention can comprise from 0.01 to 5% by weight, preferentially from 0.1 to 2% by weight of anti-corrosion agent, with respect to the total weight of the coolant.

The coolant according to the invention can further comprise at least one defoamer. The defoamer can be chosen from polyacrylates silicones, fluorinated compounds or else waxes.

The coolant used according to the invention can comprise from 0.001 to 5% by weight, preferentially from 0.1 to 2% by weight of defoamer, with respect to the total weight of the coolant.

The coolant used according to the invention can further comprise at least one pour point depressant (PPD) additive. By slowing down the formation of paraffin crystals, the pour point depressant additive generally improves the behavior of the composition under cold conditions. Examples of pour point depressant additives include alkyl polymethacrylates, polyacrylates, polyarylamides, polyalkylphenols, polyalkylnaphthalenes, alkyls polystyrenes.

The coolant used according to the invention can further be one or a plurality of fluorocarbon compounds. Fluorocarbon compounds include perfluorooctyl bromide.

The coolant used according to the invention can comprise from 0.01 to 10%, preferentially from 0.1 to 5% by weight, advantageously from 0.5 to 2% by weight of fluorocarbon compounds, with respect to the total weight of the coolant.

The coolant according to the invention can further comprise at least one anti-wear agent. According to one embodiment, the anti-wear agent is chosen from phosphorus-containing anti-wear, phosphorous-sulfur-containing anti-wear, phosphorous-amine anti-wear, and mixtures thereof, preferably from phosphorus-containing anti-wear agents.

According to one embodiment, the anti-wear agent is a phosphite polymer, preferably corresponding to formula (I):

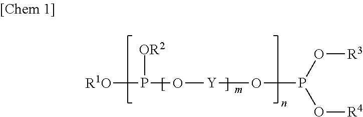

wherein,
   each of R1, R2, R3 and R4 may be chosen, independently from each other, from the moieties C1-C20 alkyl, C3-C22 alkenyl, C6-C40 cycloalkyl, C7-C40 cycloalkenyl, C1-20 methoxy alkyl glycol ethers and Y—OH;
   Y is selected from the moieties C2-C40 alkylene, C2-C40 alkyl lactone, —R7-N(R8)-R9-, wherein R7, R8 and R9 are chosen, independently from each other, from hydrogen, C1-C20 alkyl, C3-C22 alkenyl, C6-C40 cycloalkyl, C7-C40 cycloalkenyl, C1-20 methoxy alkyl glycol ethers,
   m is an integer from 2 to 100,
   n is an integer from 1 to 1000.

According to one embodiment, the phosphite polymer, preferably corresponding to formula (I), has a weight-average molecular weight of less than 30,000 g/mol, preferably ranging from 3000 to 20,000 g/mol. The weight-average molecular weight can be measured by steric exclusion chromatography.

According to one embodiment, the phosphite polymer, preferably corresponding to formula (I), has a number-average molecular weight of less than 10,000 g/mol, preferably ranging from 1000 to 5000 g/mol. The number-average molecular weight can be measured by size exclusion chromatography.

According to one embodiment, the phosphite polymer, preferably corresponding to formula (I), has a polydispersity index ranging from 1 to 5, preferably ranging from 2 to 4.

The phosphite polymer which can be used in the invention can be obtained according to the method described in document WO2011102861. More particularly, the polymer may be obtained according to the method described in paragraphs 27 to 32 of said document.

According to one embodiment, the anti-wear additives are chosen from phosphorus-sulfur additives such as metal alkylthiophosphates, more particularly zinc alkylthiophosphates, and more specifically zinc dialkyldithiophosphates or ZnDTP. Preferred compounds have the formula Zn((SP(S)(OQ²)(OQ³))₂, wherein QR² et Q³—either identical or different—independently represent an alkyl moiety, preferentially an alkyl moiety including from 1 to 18 carbon atoms.

Mention may be made, as an example, of phosphorous-sulfur anti-wear additives, monobutylthiophosphate, monooctylthiophosphate, monolaurylthiophosphate, dibutylthiophosphate, dilaurylthiophosphate, tributylthiophosphate, trioctylthiophosphate, triphenylthiophosphate, monooctylthiophosphite, trilaurylthiophosphate, monolaurylthiophosphite, monobutylthiophosphite, dibutylthiophosphite, dilaurylthiophosphite, tributylthiophosphite, trioctylthiophosphite, triphenylthiophosphite, trilaurylthiophosphite and salts thereof.

Amine phosphates as well are anti-wear additives which can be used in a cooling liquid according to the invention. However, the phosphorus provided by such additives can act as a poison in catalytic systems since same generate ash. Such effects can be minimized by partially substituting the amine phosphates with additives which do not provide phosphorous, such as e.g. polysulfides, in particular sulfur-containing olefins.

The coolant used according to the invention can comprise from 0.01 to 15%, preferably from 0.1 to 10% by weight, preferentially from 1 to 5% by weight of anti-wear agent(s), with respect to the total weight of the composition.

The additives may be introduced individually and/or in the form of a mixture of additives, according to methods well known to a person skilled in the art.

Advantageously, the coolant used according to the invention has a kinematic viscosity, measured at 40 °C as per the standard ASTM D445, ranging from 1.5 to 35 mm²/s, more particularly from 2 to 25 mm²/s, even from 2.5 to 10 mm²/s.

Advantageously, the coolant used according to the invention has a kinematic viscosity, measured at 100 °C as per the standard ASTM D445, ranging from 0.5 to 7 mm²/s, more particularly from 1 to 4 mm²/s, even from 1.1 to 2.5 mm²/s.

Alternatively, the coolant used according to the invention may consist exclusively of at least one mineral or synthetic base oil, possibly bio-sourced or recycled.

The thermal and safety management method according to the invention comprises the successive steps:
a) A step of detecting a fault in at least one electrochemical cell of at least one module of the battery,
b) When a fault is detected, a step of increasing the flow-rate of the coolant through in the module(s) containing at least one faulty cell.

According to one embodiment, a cell will be said to be faulty if at least one parameter chosen from temperature and current is above or below a given threshold value.

In the framework of the invention, a module will be said to be faulty if same includes at least one faulty cell.

Thereby, typically, if no fault is detected, the flow-rate of the coolant through the battery modules is not changed.

According to one embodiment, step a) comprises the following steps:
a1) Setting a threshold value for at least one parameter selected from temperature, voltage and current,
a2) Measuring said least one parameter chosen amongst temperature, voltage and current during battery operation, where the measuring can be implemented continuously or sequentially,
a3) Comparing said at least one measured parameter and said threshold value,
a4) Detecting a fault when the measured parameter is above or below the threshold value set during step a1.

According to one embodiment, the parameter is the temperature of each module, step a) of the method according to the invention then preferably comprising the following steps:
a1) Setting a temperature threshold value not to be exceeded T1,
a2) Measuring the temperature T2 of each module,
a3) Comparing between the measured temperature and the temperature threshold value,
a4) Detecting a fault in a given module when the measured temperature of said module exceeds the threshold temperature value determined during step a1 (when T2>T1).

According to one embodiment, the parameter is the temperature of each cell, step
a) of the method according to the invention then preferably comprising the following steps:
a1) Setting a temperature threshold value not to be exceeded T1,
a2) Measuring the temperature T2 of each cell,
a3) Comparing between the measured temperature and the temperature threshold value,
a4) Detecting a fault in a given cell when the measured temperature of said cell exceeds the threshold temperature value determined during step a1 (when T2>T1).

According to one embodiment, the parameter is the temperature of the coolant at the outlet of each module, step a) of the method according to the invention then preferably comprising the following steps:
a1) Setting a temperature threshold value not to be exceeded T1, a2) Measuring the temperature T2 of the coolant at the outlet of each module, a3) Comparing between the measured temperature and the temperature threshold value, a4) Detecting a fault in a given module when the temperature measured at the outlet of said module exceeds the temperature threshold value determined during step a1 (when T2>T1).

According to one embodiment, the parameter is the temperature of the coolant at the outlet of each cell, step a) of the method according to the invention then preferably comprising the following steps:
a1) Setting a temperature threshold value not to be exceeded T1,
a2) Measuring the temperature T2 of the coolant at the outlet of each cell,
a3) Comparing between the measured temperature and the temperature threshold value,
a4) Detecting a fault in a given cell when the temperature measured at the outlet of said cell exceeds the threshold temperature value determined during step a1 (when T2>T1).

According to one embodiment, step a) comprises the following steps:
a1 Setting a threshold value for the change of at least one parameter during a predefined time, said at least one parameter being selected from temperature, voltage and current,
a2) Measuring said least one parameter chosen amongst temperature, voltage and current during battery operation, where measuring can be implemented continuously or sequentially,
a3) Detecting a fault when the threshold value set during step a1 is reached.

According to such embodiment, the fault is detected when the parameter changes too rapidly. Thereby, it is possible to set up a threshold value for said parameter, such that the value will be considered to have been reached if the parameter changes too rapidly for a given, predefined time.

If the parameter is the temperature, then the threshold value may be the variation of said temperature over a predefined period of time. Thereby, if the temperature varies very rapidly (i.e. with a certain amplitude for a given time), thereof can be considered as a sign that a cell is faulty.

By way of non-limiting example, if the temperature of the coolant at the outlet of a module or a cell varies by at least 20 °C or even by at least 10 °C, or even by at least 5 °C over a given time, e.g. of 10 seconds, then it may be considered that said cell is faulty or that said module is faulty (or includes at least one faulty cell).

By way of non-limiting example, if the temperature of a module or a cell varies by at least 20 °C or even by at least 10 °C, or even by at least 5 °C over a given time, e.g. of 10 seconds, then it can be considered that said module is faulty (or includes at least one faulty cell).

According to one embodiment, the parameter is the voltage and the fault in a cell is detected when the voltage of said cell reaches 0 V. According to such embodiment, the threshold value for the parameter is 0 V.

According to one embodiment, the fault is detected when the voltage decreases too rapidly.

By way of non-limiting example, if the voltage of at least one cell varies by at least 3 V, or even by at least 2 V, or even by at least 1 V, over a predefined time of e.g. 10 seconds, then it may be considered that said cell is faulty.

Voltage is a clear, easy to determine indicator of a failure/fault of a battery, a cell or a module.

Typically, each module comprises an inlet for adding in the coolant into said module and an outlet for extracting the coolant from said module.

According to one embodiment, each module comprises veins, called coolant veins, allowing the coolant to circulate in the module over all or part of the length of each cell within the module.

The measurement of the given parameter can be carried out continuously or sequentially, at regular intervals.

According to one embodiment, step b) of modulation of at least part of the flow-rate comprises an increase in the flow-rate of the coolant in the module or modules having at least one faulty cell and a decrease in the flow-rate of the coolant in the module or modules which do not have faulty cells.

The flow-rate modulation step b) can also be called the flow-rate redirection step.

Thereby, according to the invention, the modulation step b) is a flow-rate redirection step.

Redirection of the flow-rate means according to the present invention that at least part of the coolant circulating in the module or modules at a given flow-rate during nominal operation is redirected to the module or modules having at least one faulty cell from the module or modules which do not have any faulty cells.

According to one embodiment, variable-opening valves can be used to allow the flow-rate to be modulated during step b), said valves then preferably being located on the cooling circuit upstream of each module.

According to one embodiment, the valves are solenoid valves.

According to one embodiment of the thermal and safety management method of the invention, the flow-rate modulation step b) comprises a step of closing at least one valve upstream of at least one module not having any faulty cell(s), preferably a step of closing each valve upstream of each module which does not have any faulty cell(s).

According to one embodiment, the valves are shut-off valves serving to stop the circulation of the coolant in each module which does not have any faulty cell(s).

Thereby, typically within the framework of the invention, for a battery with X modules (the modules being in parallel, in the fluidic sense) and operating with an overall flow-rate D of coolant:
in nominal operation, each module m receives D/X % of the overall flow-rate D, i.e. the flow-rate of the coolant is distributed uniformly in each of the modules of the battery,
when a fault is detected in at least one cell of one of the modules, then said module having at least one faulty cell receives a flow-rate which will be greater than D/X %, in other words, the flow-rate is no longer distributed uniformly but the flow-rate is modulated so that the overall flow-rate received by the faulty module is greater than the overall flow-rate received by each of the other modules which are not faulty.

According to one embodiment of the management method according to the invention, the battery comprises at least 3 modules in parallel, and at least 50% of the flow-rate of the coolant is redirected to the module or modules including at least one faulty cell, preferably at least 70% of the flow-rate, else preferably at least 90% of the flow-rate, or even 100% of the flow-rate of the coolant is directed to the module or modules including at least one faulty cell.

According to one embodiment, from 50% to 90% of the flow-rate of the coolant is redirected to the module or modules having at least one faulty cell, so that the module or modules which do not have any faulty cell or cells continue to be in contact with the coolant.

According to one embodiment of the management method according to the invention, the modulation step b) is implemented until the faulty cell or cells return to nominal operation.

As defined by the present invention, a cell having nominal operation henceforth is not considered to be faulty.

Preferably, when the faulty cell has a temperature below 100 °C, preferably 50 °C, then it is considered to have a nominal operation. Thereby, according to one embodiment of the management method according to the invention, step b) of modulation of the flow-rate is implemented until the faulty cell or cells regain a temperature below 100 °C, preferably 50 °C.

According to one embodiment, the thermal and safety management method is implemented via a device.

According to one embodiment, the device for implementing the thermal and safety management method comprises a temperature sensor for the coolant at the inlet of the battery and a temperature sensor for the coolant at the outlet of the battery.

According to one embodiment, the device for implementing the thermal and safety management method comprises a temperature sensor for the coolant making it possible to determine the temperature of the coolant at the outlet of each module and/or each cell. Such embodiment is particularly relevant when the parameter determined is the temperature of the coolant at the outlet of each module and/or each cell.

According to one embodiment, the device for implementing the thermal and safety management method comprises a temperature sensor for determining the temperature of each module and/or of each cell. Such embodiment is particularly relevant when the determined parameter is the temperature of each module and/or of each cell.

Thereby, according to a particularly advantageous embodiment, the device comprises a battery and a cooling circuit, the battery includes a plurality of modules, each module includes a plurality of cells and the cooling circuit comprises a circulation loop for a coolant and control valves for regulating the flow-rate of said coolant upstream of each module, the coolant circulating at a given flow-rate in nominal operation and being in direct contact with the cells, and the thermal and safety management method of the invention advantageously comprises the steps:
a1) Setting a threshold value for at least one parameter selected from temperature, voltage and current,
a2) Measuring at least one parameter selected from temperature, voltage and current during battery operation,
a3) Detecting a fault when the measured parameter is above or below the threshold value set during step a1,
b) When a fault is detected, a flow-rate redirection step comprising (i) increasing the flow-rate of coolant through the module(s) having at least one faulty cell and (ii-1) decreasing the flow-rate of coolant through the module(s) not having at least one faulty cell or (ii-2) stopping the flow-rate of coolant through the module(s) not having at least one faulty cell.

Thereby, according to a particularly advantageous embodiment, the device comprises a battery and a cooling circuit, the battery including a plurality of modules, each module including a plurality of cells and the cooling circuit comprising a circulation loop for a coolant and control valves for regulating the flow-rate of said coolant upstream of each module, the coolant circulating at a given flow-rate in nominal operation and being in direct contact with the cells, and the thermal and safety management method of the invention advantageously comprising the steps:
a1) Setting a temperature threshold value, not to be exceeded, of each module or of each cell,
a2) Measuring the temperature of each module of each cell,
a3) Detecting a fault in at least one given module or at least one given cell, when the measured temperature of said module or of said cell exceeds the temperature threshold value,
b) When a fault is detected, a flow-rate redirection step comprising (i) increasing the flow-rate of coolant through the module(s) having at least one faulty cell and (ii-1) decreasing the flow-rate of coolant through the module(s) not having at least one faulty cell or (ii-2) stopping the flow-rate of coolant through the module(s) not having at least one faulty cell.

A further subject matter of the invention is a device comprising:
A battery including a plurality of modules, each module including a plurality of electrochemical cells,
A cooling system including:
   a circulation loop for a coolant,
   at least one valve upstream of each module for controlling the flow-rate of the coolant.

According to one embodiment, the device further comprises a control unit for detecting at least one faulty cell.

According to one embodiment, the device further comprises at least one sensor at the outlet of each module or, for measuring at least one parameter chosen from the temperature, the voltage and the current.

According to one embodiment, the device further comprises at least one heat exchanger intended to be connected to an air conditioning circuit wherein a refrigerant fluid flows.

Thereby, according to one particular embodiment of the invention, the device comprises:
a battery including a plurality of modules, each module including a plurality of electrochemical cells,
an exchanger, also called a radiator, for discharging part of the calories stored by the coolant to the outside air,
a chiller (e.g. such as a plate heat exchanger) allowing heat to be exchanged with air or with another coolant circuit reserved for the vehicle air conditioning (so-called “refrigerant” fluid),
if appropriate, a heating system for increasing the temperature of the coolant in order to warm the battery during a cold start or when the vehicle is operating in a cold atmosphere,
at least one pump,
a circulation loop for a coolant and
valves to set in motion and manage flow-rates throughout the circuit.

The features and the advantages defined for the management method according to the invention further apply to the device according to the invention.

According to one embodiment, the device according to the invention further comprises a temperature sensor for the coolant at the inlet of the battery and a temperature sensor for the coolant at the outlet of the battery.

According to one embodiment, the device according to the invention further comprises a temperature sensor for the coolant for determining the temperature of the coolant at the outlet of each module and/or each cell. Such embodiment is particularly relevant when the parameter determined is the temperature of the coolant at the outlet of each module and/or each cell.

According to one embodiment, the device according to the invention further comprises a temperature sensor for determining the temperature of each module and/or of each cell. Such embodiment is particularly relevant when the determined parameter is the temperature of each module and/or of each cell.

According to one embodiment, the device comprises, in addition to the cooling circuit, an air conditioning circuit. Such an air conditioning circuit can exchange heat via the chiller of the cooling circuit and can further comprise a compressor, an expansion valve and a condenser. The air conditioning circuit can circulate a refrigerant fluid, e.g. a hydrofluoroolefin, such as HFO-1234yf.

According to such embodiment, a heat exchange can take place via the chiller between the coolant and the refrigerating fluid.

A compressor may be present in the air conditioning system. The function of the compressor is to raise the pressure level of the refrigerating fluid, in the gaseous phase at the outlet of the exchanger, before the passage and liquefaction thereof in the condenser.

An expansion valve, such as an electronic expansion valve, may be present in the air conditioning system. Such a valve lowers the pressure and controls the flow-rate of the refrigerating fluid at its outlet from the condenser, in order to maximize the efficiency of the plate heat exchanger. Indeed, the valve can make the pressure of the coolant drop so that the latter is under temperature and pressure conditions very close to the liquid-vapor equilibrium thereof and let through the optimum quantity of coolant so that the phase change (made possible by adding the heat supplied by the coolant) is complete.

A condenser may be present in the air conditioning system. Such a condenser serves to convert the pressurized gas at the outlet of the compressor into a pressurized liquid.

The invention can be used in an electric vehicle, in order to avoid the thermal runaway of the battery. Thereby, the device according to the invention can be used in an electric and hybrid vehicle, in particular a rechargeable hybrid vehicle.

“Electric vehicle” as defined by the present invention refers to a vehicle comprising an electric motor as the only means of propulsion, whereas a hybrid vehicle comprises an internal combustion engine and an electric motor as combined means of propulsion.

“Means of propulsion” as defined by the present invention, refers to a system comprising the mechanical parts required for the propulsion of an electric vehicle. The propulsion system thereby encompasses more particularly an electric motor comprising the rotor-stator assembly of power electronic systems (dedicated to speed regulation), a transmission, and a battery.

The device according to the invention can also be used in an energy storage assembly or in an aircraft.

The invention will now be described by means of the following examples, given of course as an illustration of the invention, but not limited to.

### EXAMPLES

In order to demonstrate the advantages of the management method of the invention, a model was implemented using the software Simulation X.

The model consists of a battery pack with 16 modules of 6 cells in an 8p2s configuration (2 rows of 8 modules in parallel). The modeled cells are “Pouch” cells with a height of 276 mm, a length of 176 mm and a thickness of 8 mm and a capacity of 40 Ah with NMC technology.

From a hydrodynamic point of view, the heat-transfer fluid (coolant) thus circulates in fluid veins of rectangular section (height of 276 mm and width of 2 mm) over the entire length of the cells (176 mm). Two buffer zones at the inlet and outlet of the module provide a uniform distribution of flow-rates between each of the fluid veins. Same have a thickness of 5 mm, a height of 276 mm and a width equivalent to 6 cells and 6 fluid veins, i.e. 60 mm.

From a system modeling point of view, the 3D configuration is approximated using fluid volumes (2 volumes corresponding to buffer zones and 6 volumes corresponding to fluid veins) and pipes of rectangular cross-section to calculate the pressure drop generated by the circulation of the coolant.

The cells are represented by solid thermal capacities parameterized by the dimensions (mentioned hereinabove) thereof, the density (2700 kg·m⁻³) and the specific heat capacity (900 J·kg⁻¹·K⁻¹).

Furthermore, as can be seen in FIG. 4, each cell is connected to a controllable heat source, leaving the possibility of studying nominal operation or thermal runaway configurations as desired.

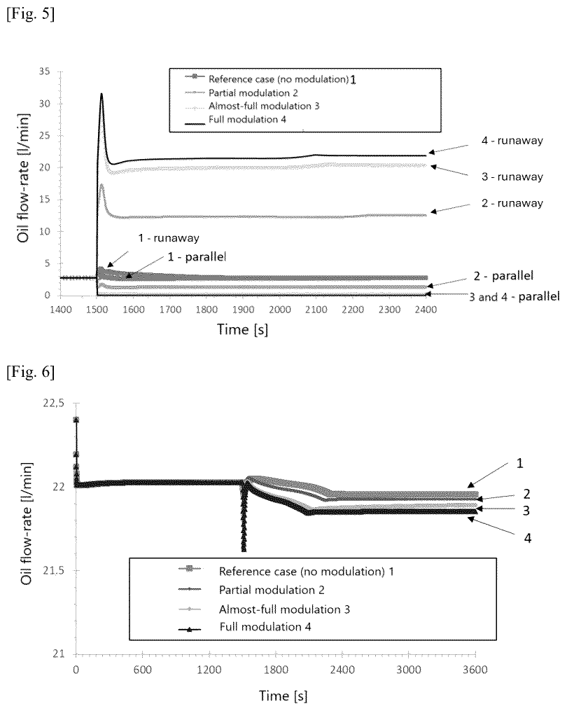

To finish the system model of the module, the thermal-fluidic coupling, i.e. the heat transfer between the cells (solid thermal capacities) and the coolant (fluid volumes), was carried out using a function, representing the heat transfer coefficient as a function of the mean velocity of the flow-rate in the fluid veins, calculated from 3D simulations (see FIG. 5).

In the selected configuration (8p2s), the choice was made to generate runaway in one of the cells of one of the modules of the first row. Such a configuration has a higher criticality insofar as the coolant leaving the module subject to runaway will have to pass through the modules of the second row.

Assuming that the coolant supplying all the modules is homogenized upstream and downstream of the modules (by manifolds e.g.), it becomes possible to digitally simplify the configuration by considering that all the modules of the same row that do not directly experience runaway, will behave strictly identical.

The pump chosen in the present study is a positive displacement pump which has the advantage of operating with a high level of efficiency. The pump is speed-controlled and provides a variable flow-rate as a function of the pressure level (and hence of the head losses) present in the fluid circuit. The advantage of operating with iso-speed control is to be able to quantify the efficiency of the modulation of the flow-rate distribution by taking into account possible increases in head losses.

The valves are the elements that serve for the modulation of the flow-rate between the different modules and in particular between the module undergoing the runaway and the other modules. In the model, variable-opening valves were used to precisely control the flow-rate distribution.

Different opening levels have been tested for modules parallel to the module undergoing runaway:
100% corresponding to the case where each module receives an “equal” part of the flow-rate (in reality, the flow-rate increases very slightly in the module during runaway because of the decrease in the head losses caused by the heating of the coolant);
30% corresponding to the case where slightly more than half of the coolant (57.3%) passes into the module undergoing runaway;
10% corresponding to the case where most of the coolant (93.3%) passes through the module undergoing the runaway and only a slight circulation is maintained in the parallel modules.
0% corresponding to the case where all the flow-rate delivered by the pump is redirected to the module during runaway.

It should be noted that in all cases where the flow-rate is modulated in favor of the module undergoing the runaway, the modulation is synchronized temporally with the breakout of the runaway.

The developed model contains three temperature probes and one pressure probe. The temperature sensors are used to measure the temperatures of the coolant upstream of the battery pack, at the outlet of the module during runaway and at the outlet of the battery pack. The pressure sensor is placed upstream of the pump in order to calculate the exact head losses of the system and to adapt the flow-rate of the pump.

The coolant used for the study is an oil with the following characteristics:
Density at 25 °C of 0.7740 g/cm3
Density at 50 °C of 0.7650 g/cm3
Density at 100 °C of 0.7225 g/cm3
Kinematic viscosity at −25 °C of 27 mm²/s
Kinematic viscosity at 0 °C of the order of 9 mm²/s
Kinematic viscosity at 40 °C of the order of 3 mm²/s
Kinematic viscosity at 100 °C of the order of 1 mm²/s
Thermal conductivity at 40 °C on the order of 0.1275 W/(m·K)
Thermal conductivity at 80 °C on the order of 0.1175 W/(m·K)
Heat capacity of 2100 J·kg⁻¹·K⁻¹.

The model further includes an air conditioning system including a plate heat exchanger (chiller), a compressor, an electronic expansion valve and a condenser.

The plate heat exchanger allows the battery circuit coolant to be cooled. The heat exchange is generated by the phase change (liquid-vapor) of a refrigerating fluid (R1234yf). The exchanger has a height of 170 mm, a width of 80 mm and a thickness of 68 mm. Each plate has a thickness of 0.35 mm and the exchanger has 0.78 plates per mm.

The function of the compressor is to raise the pressure level of the refrigerating fluid, in gaseous phase at the outlet of the exchanger, before the passage and liquefaction thereof in the condenser.

For a given compressor geometry, the pressurization level can be controlled directly by adjusting the power consumed or the rotation speed. In the present model, it is the second parameter that is adapted by the control strategy in order to satisfy the temperature setpoint for the coolant at the inlet of the battery pack.

The setpoint temperature is 25 °C in the stabilized operating phase and 20 °C from the breakout of the thermal runaway until the end of the simulation.

It should be noted that to maintain consistency in the dynamics of the response of the compressor, and more particularly to prevent an excessive increase in the speed of rotation following the increase in the temperature of the coolant during the thermal runaway, threshold values of reaction time and speed of rotation have been imposed for the regulation.

The influence of the maximum permitted rotation speed on the performance of the exchanger and on the value of flow-rate modulation was studied in the simulations using two values: 1250 rpm and 5000 rpm.

The electronic expansion valve lowers the pressure and controls the flow-rate of the refrigerating fluid at its outlet from the condenser, in order to maximize the efficiency of the plate heat exchanger. Indeed, the valve has to make the pressure of the coolant drop so that the latter is under temperature and pressure conditions very close to the liquid-vapor equilibrium thereof and let through the optimum quantity of coolant so that the phase change (made possible by adding the heat supplied by the coolant) is complete.

In the model, as in reality, the intensity of the depressurization is controlled by a control strategy that changes the opening level of the valve in order to satisfy a setpoint of 5 °C on the runaway of the refrigerating fluid at the outlet of the exchanger. Such a setpoint ensures that the entire refrigerating fluid has changed phase when the setpoint is reached. As for the compressor, threshold values have been imposed for the regulation on the valve opening level, in particular in order to prevent a full closure of the valve that could in return raise problems of convergence of the model.

As the name suggests, the function of condenser is to convert the pressurized gas at the compressor outlet into a pressurized liquid. In order to limit the number of variables in the model, all the parameters controlling the operation of the condenser have been frozen. The outside air temperature has been set at 20 °C and the pump flow-rate at 100 1/s. The condenser has a height of 590 mm, a width of 326 mm and a thickness of 29 mm. The internal diameter of the tubes is 10 mm and the wall thickness of the tubes is 1 mm. There are 48 tubes per row.

### Runaway Generation:

Each calculation consists of a time simulation of the operation of the system for a duration of one hour (3600 s) according to the following numerical protocol:
At t=0 s, a heat source of 20 W is applied to all the cells of the battery pack to represent stabilized operating conditions.
From t=0 s to t=1500 s, the control strategy implemented in the pilot air conditioning circuit increases the speed of rotation of the compressor in order to increase the amount of heat absorbed by the plate heat exchanger and satisfy the temperature requirement of 25 °C imposed for the coolant at the inlet of the battery pack.
At t=1500 s, when the system is perfectly stabilized (i.e. no evolution of the main variables solved in the two circuits), the thermal runaway event is generated by imposing, on one of the cells (cell no.2) of a module of the first row, a dissipated thermal power of 722.67 kW, during 10 s. The flow-rate modulation is immediately activated (in cases where same is tested) and the temperature setpoint for the coolant entering the battery pack is lowered from 25 °C to 20 °C.
From t=1510 s to t=3600 s, no heat source is applied to the battery and the control strategy is allowed to control the cooling of the fluid.

### Example 1: Reference Case

A reference configuration was simulated in order to compare with the method of the invention.

In the reference configuration, flow-rate is uniformly shared between each of the modules, without redirection.

The oil pump operates at a speed of 3000 rpm and the compressor has a limit of speed of rotation of 5000 rpm.

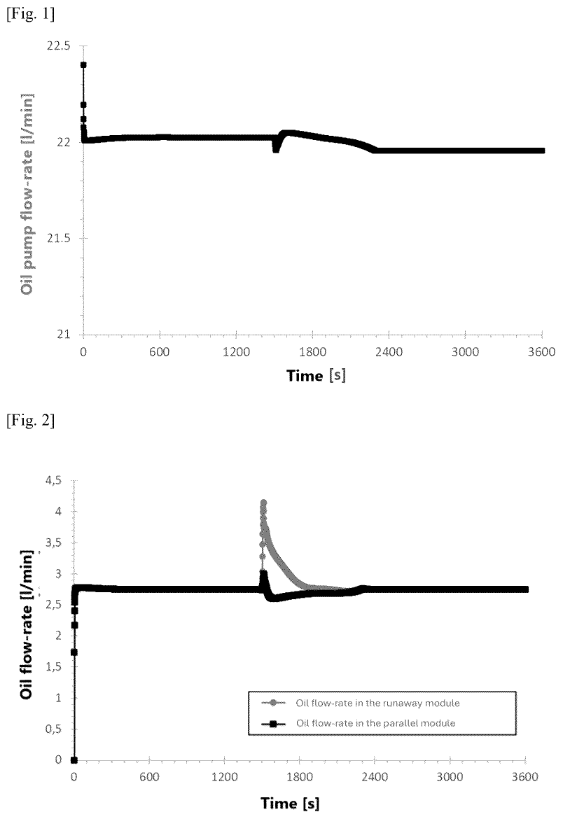

The results obtained for the reference case are presented in FIG. 1 to FIG. 4.

FIG. 1 shows that the oil pump flow-rate remains relatively stable (around 221/min) throughout the simulation. Some fluctuations are visible at the breakout of the runaway (at t=1500 s). In the absence of modulation, such variations are essentially generated by the variations in heat losses linked to the variations of temperature of the coolant.

FIG. 2 shows that the flow-rate of the coolant in the packaged module increases slightly at the time of breakout of the thermal runaway.

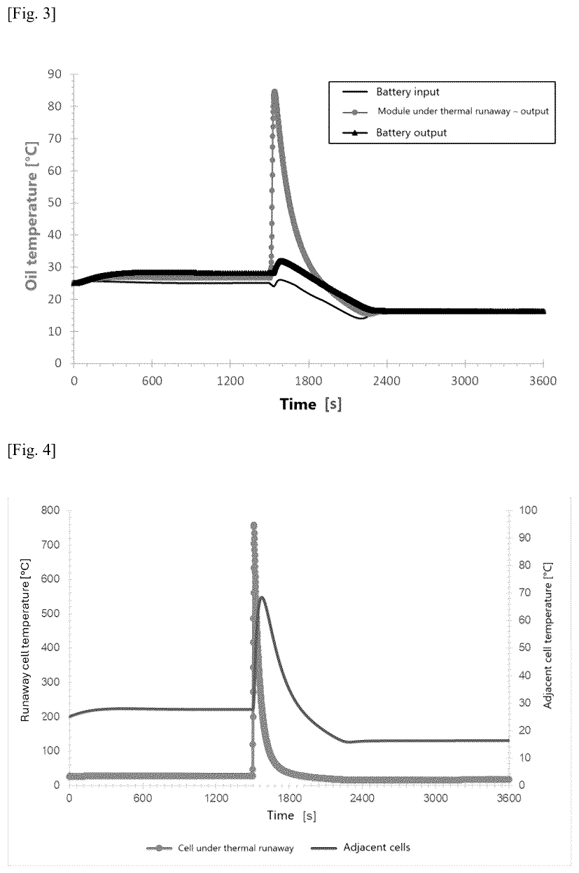

FIG. 3 shows that the temperature of the coolant at the outlet of the module containing the faulty cell increases sharply, while the temperature of the coolant at the inlet and outlet of the battery remains relatively stable.

At the breakout of the runaway in one of the modules in the first row, the temperature of the coolant decreases slightly in all the other modules due to the cut-off of the power to the cells (which had previously dissipated 20 W of heat continuously). A slight increase in the head losses and a reduction in the flow-rate results therefrom. As the fluid recovers the heat generated by the thermal runaway of a cell, the flow-rate temporarily increases again before decreasing again as the fluid cools down.

FIG. 4 shows that the temperature of the cell adjacent to the faulty cell (packaged cell) reaches 67 °C. Such temperature may seem relatively low and sufficient to prevent any risk of propagation, but it should be noted that the model does not take into account certain phenomena, such as e.g. the release of gas at very high temperature and the narrowing of the coolant veins due to the swelling of the packaged cell, which have a negative influence on the situation. FIG. 4 shows that the faulty cell reaches a temperature above 750 °C.

The model presented is thus a good model for evaluating the technical advantage of the invention.

### Example 2: Flow-Rate Redirection (Modulation)

In such example, the results for 3 levels of modulation (or redirection) are compared to the reference configuration (example 1).

The intensity of the modulation is presented in FIG. 5 as the flow-rate distribution between the packaged module and the parallel modules.

Thereby, four modulation configurations were tested, corresponding respectively to ratios of coolant flow-rate in the module experiencing runaway relative to the overall flow-rate of
12.5% (reference case),
57.3% (partial opening or partial modulation),
93.3% (minimum aperture or almost full modulation) and
100% (closed or full modulation).

FIG. 5 shows, for each modulation configuration, the flow-rate in the module with the cell undergoing runaway, in the upper part of the graph, and the flow-rate in the parallel modules, in the lower part of the graph.

As can be seen in FIG. 6, the flow-rate modulation leads to slight variations in the flow-rate of the pump. The latter decreases as the flow-rate increases in the module undergoing runaway. The decrease is explained by an increase in head losses in the system.

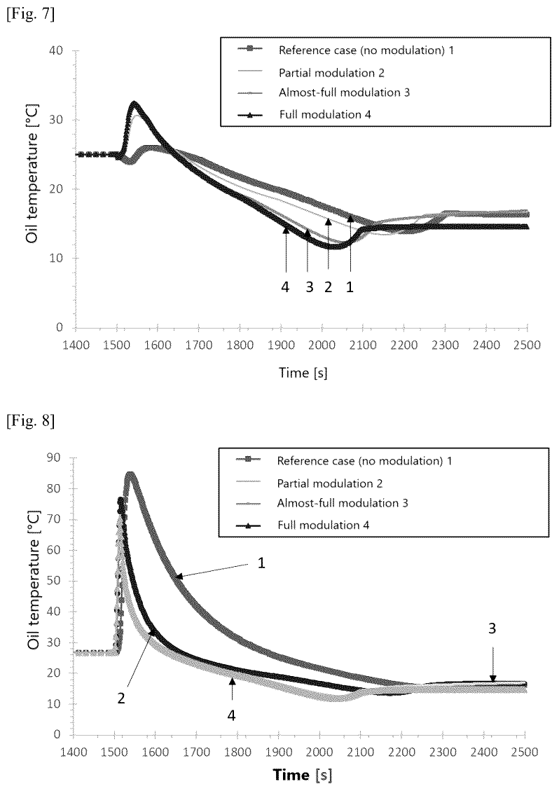

FIG. 7 shows the trend of the temperature of the fluid at the inlet of the battery for each of the 4 modulation configurations.

FIG. 8 shows the trend of the temperature of the fluid at the outlet of the module undergoing runaway for each of the 4 modulation configurations.

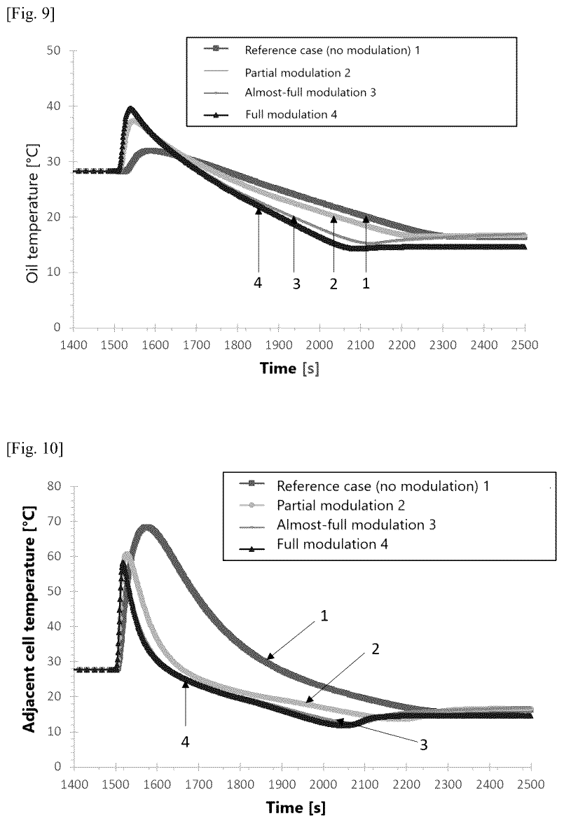

FIG. 9 shows the trend of the temperature of the fluid at the outlet of the battery for each of the 4 modulation configurations.

As can be seen from the comparison of FIG. 5 to FIG. 9, the head losses are controlled to first order by the increase in the speed in the module undergoing runaway (non-linear dependency).

The decrease in the overall flow-rate in the circuit when modulation takes place is an important result because it could be expected that same entails a deterioration in the thermal management of the battery during runaway. However, thereof is not what is observed at the cell temperatures of the module undergoing runaway.

FIG. 10 shows the trend in the temperature of the cells adjacent to the cell undergoing runaway, for each of the 4 modulation configurations.

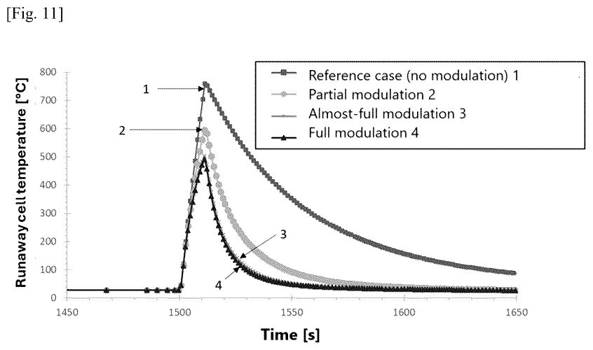

FIG. 11 shows the trend in the temperature of the cell undergoing runaway, for each of the 4 modulation configurations.

As shown by the curves in FIG. 10 and FIG. 11, the flow-rate modulation leads to a significant reduction of the temperatures, both for the cell under runaway and for the adjacent cells. Specifically, the maximum temperatures of the cell under runaway and of the adjacent cells change correspondingly, from 752 °C and 68.3 °C in the reference case to 489 °C and 58.2 °C in the case where the entire flow-rate of coolant is redirected to the module under runaway.

Furthermore, the dynamics of cooling is greatly improved by the modulation of the flow-rate. In the two most favorable cases, i.e. where the coolant is essentially redirected to the module under runaway, the adjacent cells regain the pre-runaway temperature thereof in less than 103 s.

In the absence of modulation, the cooling time is multiplied by a factor of 3.5 (FIG. 10).

The modulation of the flow-rates, in favor of the module(s) under runaway, thus serves to significantly limit the rise in temperature of the cells during runaway and of the neighbors thereof, thereby reducing the risks of propagation of the runaway. Such a result is thus a major gain in terms of safety.

The flow-rate modulation will also have a positive effect on the lifetime of cells that have not directly undergone runaway by reducing the thermal stress (a combination of factors such as the maximum temperature reached, the duration of the runaway and the homogeneity of temperatures within the cell) experienced.

1.-15. (canceled)

16. A method of thermal and of safety management of a battery in a device, said device comprising a battery and a cooling circuit, the battery including a plurality of modules, each module including a plurality of cells and the cooling circuit comprising a circulation loop for a coolant and regulating valves for regulating the flow-rate of said coolant upstream of each module, the method comprising the steps:
a) A step of detecting a fault in at least one cell of a module,
b) When a fault is detected, a flow-rate redirection step that includes an increase in the coolant flow-rate through the module(s) containing at least one faulty cell.

17. The method according to claim 16, wherein at least 50% of the flow-rate of the coolant is redirected to the module or modules including at least one faulty cell.

18. The method according to claim 16, wherein step a) comprises the following successive steps:
a1) Setting a threshold value for at least one parameter selected from temperature, voltage and current,
a2) Measuring at least one parameter selected from temperature, voltage and current during battery operation,
a3) Detecting a fault when the measured parameter is above or below the threshold value set during step a1.

19. The method according to claim 18, wherein the parameter is the temperature of the coolant, said method comprising:
a1) Setting a temperature threshold value not to be exceeded,
a2) Measuring the coolant temperature at the outlet of each module or at the outlet of each cell,
a3) Detecting a fault in at least one given module or cell, when the temperature measured at the outlet of that module or cell exceeds the temperature threshold value,
b) Redirecting at least part of the flow-rate of the coolant toward said faulty module or the module including said faulty cell.

20. The method according to claim 18, wherein the parameter is the temperature of each module or of each cell, said method comprising:
a1) Setting a temperature threshold value, not to be exceeded, of each module or of each cell,
a2) Measuring the temperature of each module of each cell,
a3) Detecting a fault in at least one given module or at least one given cell, when the measured temperature of said module or of said cell exceeds the temperature threshold value,
b) Redirecting at least part of the flow-rate of the coolant toward said faulty module or the module including said faulty cell.

21. The method according to claim 16, wherein step a) comprises the following successive steps:
a1) Setting a threshold value for the change of at least one parameter during a given time, said at least one parameter being selected from temperature, voltage and current,
a2) Measuring said parameter during battery operation,
a3) Detecting a fault in at least one given module or at least one given cell, when said threshold value is exceeded.

22. The method according to claim 16, wherein step b) further comprises a reduction in the flow-rate of the coolant in the module or modules which do not have faulty cells.

23. The method according to claim 16, wherein the modulation step b) is implemented until the faulty cell or cells return to nominal operation.

24. A device for implementing the method according to claim 16, said device comprising:
A battery including a plurality of modules, each module including a plurality of electrochemical cells,
A cooling system including:
a circulation loop for a coolant,
at least one valve upstream of each module for controlling the flow-rate of the coolant.

25. The device according to claim 24, wherein said at least one valve is a shut-off valve serving to stop the circulation of the flow-rate in the module not comprising any faulty cell(s).

26. The device according to claim 24, further comprising a control unit for detecting at least one faulty cell.

27. The device according to claim 24, further comprising at least one sensor at the outlet of each module or each cell, making it possible to measure at least one parameter chosen from the temperature of the coolant and the current.

28. The device according to claim 24, further comprising an air conditioning circuit wherein a refrigerant fluid flows.

29. The device according to claim 28, wherein the cooling circuit further comprises at least one heat exchanger intended to exchange heat with the air or with a refrigerant fluid of the air conditioning circuit.

30. The device according to claim 24, wherein the cooling circuit further comprises at least one heat exchanger intended to exchange heat with the air.

31. The method according to claim 16, wherein at least 70% of the flow-rate of the coolant is redirected to the module including a faulty cell.

32. The method according to claim 16, wherein at least 90% of the flow-rate of the coolant is redirected to the module including a faulty cell.

33. The method according to claim 16, wherein 100% of the flow-rate of the coolant is redirected to the module including a faulty cell.

34. The device according to claim 24, wherein the coolant is a non-aqueous coolant.

35. The device according to claim 34, wherein the coolant is in direct contact with the cells.
